(19) United States
(12) Patent Application Publication
(10) Pub. No.: US 2020/0150793 A1
(43) Pub. Date: May 14, 2020

(54) FLEXIBLE TOUCH FILM AND DEVICE THEREOF

(71) Applicant: INT TECH CO., LTD., Hsinchu County (TW)

(72) Inventor: KUO-CHENG HSU, TAICHUNG CITY (TW)

(21) Appl. No.: 16/189,184

(22) Filed: Nov. 13, 2018

(51) Int. Cl. G06F 3/044

(52) U.S. Cl. CPC G06F 3/044; H01L 27/323

(57) ABSTRACT

A flexible touch film includes a first electrode layer, a second electrode layer and an insulator electrically isolating the first electrode layer and the second electrode layer is provided. The first electrode layer extends continuously along a first direction; the second electrode layer extends continuously along a second direction and discontinuously along the first direction; and the insulator is disposed between the first and the second electrode layers. A flexible touch device thereof is also provided.

### TECHNICAL FIELD

The present disclosure is related to a flexible touch film and a device thereof.

### BACKGROUND

A touchscreen is an input and output device usually layered on the top of an electronic visual display. A user can give input or control the information processing system by touching the screen through one or more fingers, a stylus or a special pen to substitute (or be an alternative of) the use of a mouse or a control remote. The touchscreen enables the user to interact directly with what is displayed, rather than using a mouse, a key board, or other such devices (other than a stylus, which is optional for most modern touchscreens). As a marketing tendency of easy carrying, take and use, and easy controlling, which is especially important for elders and children, the touchscreen provides high convenience and has become a main stream in display market.

### SUMMARY

From an aspect, the present disclosure provides a flexible touch film, including a first electrode layer, a second electrode layer, and an insulator disposed between the first and the second electrode layers and electrically isolating the first electrode layer and the second electrode layer. The first electrode layer extends continuously along a first direction and the second electrode extends continuously along a second direction and discontinuously along the first direction, wherein the first direction is substantially perpendicular to the second direction.

In an embodiment of the present disclosure, a material of the first electrode layer is different from that of the second electrode layer.

In an embodiment of the present disclosure, a minimum bend radius of the first electrode layer is smaller than a minimum bend radius of the second electrode layer.

In an embodiment of the present disclosure, the film further includes a bending area across a sensing area of the flexible touch film along the second direction, wherein a percentage of an area coverage of the second electrode layer distributed in the bending area is (a bend radius of the film/a length of the sensing area along the second direction)*100% when the film is bent.

In an embodiment of the present disclosure, the second electrode layer is discontinuously and evenly distributed in the bending area along the first direction.

In an embodiment of the present disclosure, the second electrode layer includes a plurality of electrodes extends along the second direction and disposed in parallel along the first direction, and distances between adjacent electrodes are different along the first direction.

In an embodiment of the present disclosure, distances between adjacent electrodes are ascending along the first direction.

In an embodiment of the present disclosure, the first electrode layer, the insulator and the second electrode layer are stacked in sequence, and the first electrode layer has a bend radius smaller than that of the second electrode layer when the film is bent.

In an embodiment of the present disclosure, the second electrode layer, the first insulator and the first electrode layer are stacked in sequence, and the second electrode layer has a bend radius smaller than that of the first electrode when the film is bent.

In an embodiment of the present disclosure, the first electrode layer includes: a first part having a first width on the second direction; and a second part having a second width on the second direction, the second width being smaller than the first width.

In an embodiment of the present disclosure, the second part traverses the bending area on the first direction.

From another aspect, the present disclosure provides a flexible touch device, including a substrate, a first electrode layer, a second electrode layer, and an insulator disposed between the first and the second electrode layers. The first electrode layer extends continuously along a first direction over the substrate and the second electrode layer extends continuously along a second direction and discontinuously along the first direction over the substrate, wherein the first direction is substantially perpendicular to the second direction.

In an embodiment of the present disclosure, the substrate is a flexible display panel.

In an embodiment of the present disclosure, a material of the first electrode layer is different from that of the second electrode layer.

In an embodiment of the present disclosure, a minimum bend radius of the first electrode layer is smaller than a minimum bend radius of the second electrode layer.

In an embodiment of the present disclosure, the first electrode layer is between the substrate and the insulator.

In an embodiment of the present disclosure, a plurality of second electrodes is electrically connected with a plurality of contacts, and a bending area of the device is between two adjacent contacts.

In an embodiment of the present disclosure, the second electrode layer is between the substrate and the insulator.

In an embodiment of the present disclosure, the second electrode layer includes a plurality of the electrodes, which is electrically connected with a plurality of contacts, and a contact traverses a bending area of the device.

In an embodiment of the present disclosure, the first electrode layer includes: a first part having a first width on the second direction; and a second part having a second width on the second direction, the second width being smaller than the first width.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a top view of a flexible touch film in accordance with an embodiment of the present disclosure.

FIG. 2 and FIG. 3 are cross sections of the flexible touch film along a line A-A′ and a line B-B′ respectively in FIG. 1.

FIG. 4 is a cross section of the flexible touch film along the line B-B′ in FIG. 1 when the flexible touch film is bent to its minimum bend radius.

FIG. 5 is a top view of a flexible touch film in accordance with an embodiment of the present disclosure.

FIG. 6 and FIG. 7 are cross sections of the flexible touch film along a line A-A′ and a line B-B′ respectively in FIG. 5.

FIG. 8 is a cross section of the flexible touch film along the line B-B′ in FIG. 5 when the flexible touch film is bent to its minimum bend radius.

FIG. 9 shows a top view of a flexible touch film in accordance with an embodiment of the present disclosure.

FIG. 10, FIG. 11, and FIG. 12 are cross sections of the flexible touch film along a line A-A′, a line B-B′ and a line C-C′ respectively in FIG. 9.

FIG. 13 is a cross section of the flexible touch film along the line C-C in FIG. 9 when the flexible touch film is bent to its minimum bend radius.

FIG. 14, FIG. 15 and FIG. 16 are top views of flexible touch films in accordance with different embodiments of the present disclosure.

FIG. 17 is a top view of a flexible touch device in accordance with an embodiment of the present disclosure.

FIG. 18 and FIG. 19 are cross sections of the flexible touch device along a line A-A′ and a line B-B′ respectively in FIG. 17,

FIG. 20 is a cross section of the flexible touch device along the line B-B′ in FIG. 17 when the flexible touch panel is bent to its minimum bend radius.

FIG. 21 is a top view of a flexible touch device in accordance with an embodiment of the present disclosure.

FIG. 22, FIG. 23 and FIG. 24 are cross sections of the flexible touch device along a line A-A′, a line B-B′ and a line C-C′ respectively in FIG. 21.

FIG. 25 is a cross section of the flexible touch device along the line B-B′ in FIG. 21 when the flexible touch device is bent to its minimum bend radius.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

In one or more embodiments of the present disclosure, a flexible touch film having a top electrode and a bottom electrode with different materials is provided. The top electrode and the bottom electrode traverse a sensing area on two perpendicular directions respectively. From a cross sectional perspective, one of the two electrodes extends continuously along a first direction, and the other electrode extends continuously along a second direction and discontinuously along the one direction, wherein the first direction is substantially perpendicular to the second direction. And the capacitor structure has a stacked direction along a direction different from the first direction and the second direction, such as a third direction which is substantially perpendicular to the first direction and the second direction. The disclosure also provides a flexible touch panel and a manufacturing process thereof.

In the following description, one or more embodiments or implementations are provided for illustrating a general concept of the disclosure. It should be noted that the embodiments or implementations provided below are not to limit the disclosure to specific embodiments or implementations. Different elements and components can be applied singularly or in combination in other embodiments or implementations as long as functions and purposes can be achieved. And for the purpose of easy understanding and brevity, reference numerals with similar or same functions and properties are repeatedly used in different embodiments and figures, but it does not intend to limit the present disclosure into specific embodiments. Properties and arrangements of different elements descripted in different embodiments can be singularly or in combination applied as long as the desired functions of a product can be achieved.

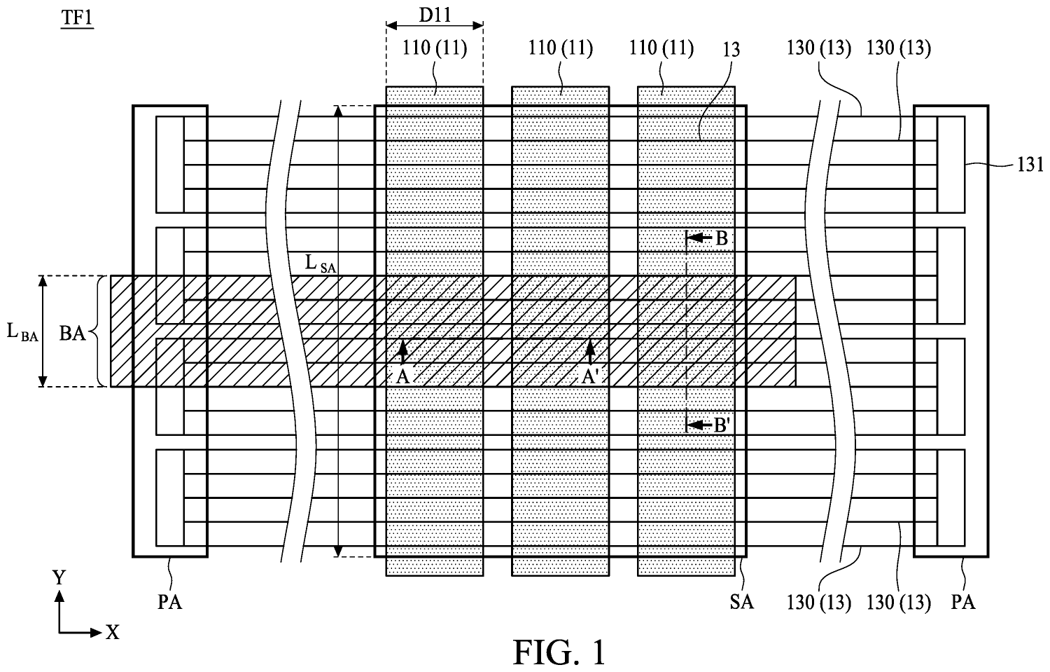

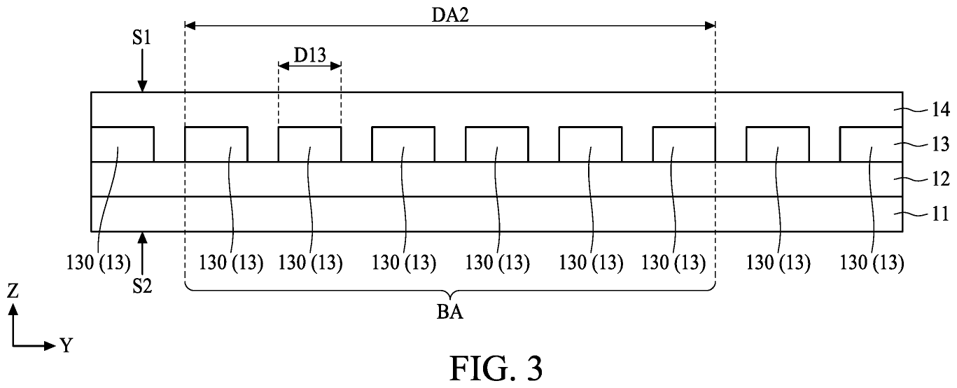

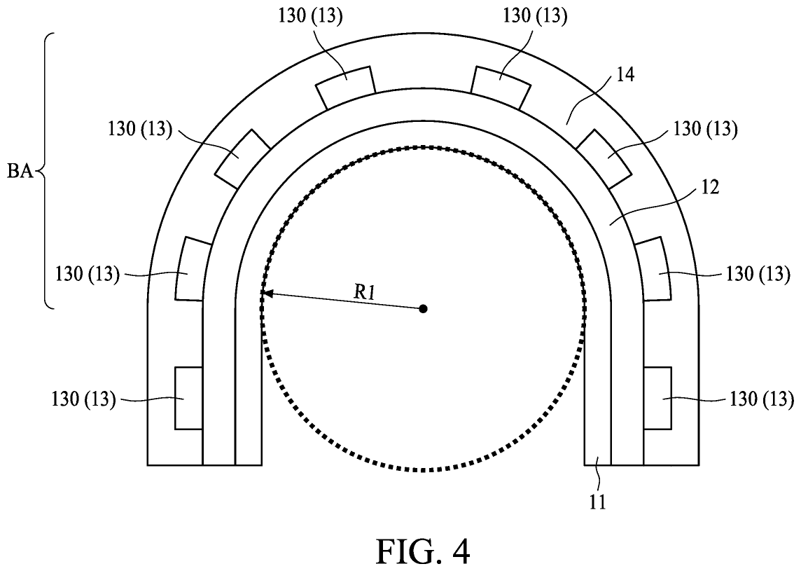

FIG. 1 shows a top view of a sensing area SA of a flexible touch film TF1 in accordance with an embodiment of the present disclosure, 2 and FIG. 3 are cross sections of the flexible touch film TF1 along a line A-A′ and a line B-B′ respectively in 1, and FIG. 4 is a cross section of the flexible touch film TF1 along the line B-B′ when the flexible touch film TF1 is bent to its minimum bend radius. Referring to FIG. 1, the flexible touch film TF1 mainly includes an electrode layer 11 having a number of electrodes 110, an insulator 12, and an electrode layer 13 having a number of electrodes 130 different from the electrode layer 11. The electrode layer 11 extends continuously along a direction Y. The electrode layer 13 extends continuously along a direction X and the electrodes 130 of the electrode layer 13 extend discontinuously along the direction Y, wherein the direction Y is substantially perpendicular to the direction X. The insulator 12 is disposed between the electrode layer 11 and the electrode layer 13 on a direction Z to electrically isolate the electrode layer 11 and the electrode layer 13, wherein the direction Z is substantially perpendicular to the direction Y and the direction X. The electrode layer 11, the insulator 12 and the electrode layer 13 are stacked in sequence on the direction Z. The flexible touch film TF1 can be bent along the direction X, and the region of the flexible touch film TF1 being bended is defined as a bending area BA. The bending area BA, for example as shown in FIG. 1, is across the sensing area SA along the direction X. The electrode layer 11 traverses the bending area BA on the direction Y, and the electrodes 130 of the electrode layer 13 is discontinuously disposed across the bending area BA on the direction Y, and every electrode 130 of the electrode layer 13 on the direction Y is parallel to one another along the direction X. In some embodiments, the electrode 110 of the electrode layer 11 has a width D11 along the direction X, the electrode 130 of the electrode layer 13 has a width D13 along the direction Y, and the width D11 is greater than the width D13,

A bend radius is measured to the inside curvature of a subject, e.g. a pipe, tube, sheet, cable, or hose, and in the embodiment, the subject can be the flexible touch film TF1, the electrode layer 11 or the electrode layer 13. A minimum bend radius is defined as a minimum radius can be bent without kinked or damaged, or shortening life of the subject. A minimum bend radius of the electrode layer 11, 13 or other elements or structures herein illustrated is measured under same conditions (e.g. same length, same width, same height, same shape, same environmental temperature, same environmental humanity). A material of the electrode layer 11 is different from that of the electrode layer 13, and the minimum bend radius of the electrode layer 11 is smaller than that of the electrode layer 13. Principles of arrangements and properties of the electrode layers 11 and 13 as above illustrated provide advantages of uses of various flexibly transparent materials while the flexible touch film TF1 can normal function on a stretchable, foldable, bendable, or rollable device or panel. Amount of manufacturing cost can be controlled by using different flexibly transparent materials, and desired flexibility of the flexible touch film can be possibly achieved by arrangements of the electrodes as described in the disclosure.

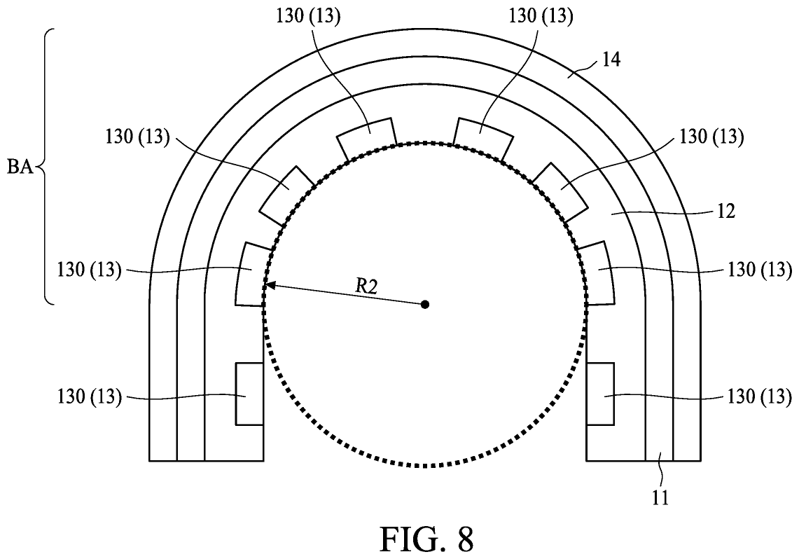

In the embodiment as shown in FIG. 4, the electrode layer 11 has a bend radius smaller than that of the electrode layer 13 when the flexible touch film TF1 is bent. For better flexibility, longer lifetime, or better sensing ability of the flexible touch film TF1, arrangement of the electrode 130 can be further adjusted. In some embodiments, the electrodes 130 are discontinuously and evenly distributed in the bending area BA along the direction Y for good sensing ability. In some embodiments, a percentage of an area coverage of the electrodes 130 of the electrode layer 13 distributed in the bending area BA is (R/L_{SA})*100% of the sensing area SA in a bending status (such as a cross section view as shown in FIGS. 4 and 8), wherein R is the bend radius of the subject and L_{SA} is a length of the sensing area SA along a bending direction (i.e. the direction Y in the embodiments). For better visualization (without screen-door effect), referring to FIGS. 3-4, two electrodes 130 are separated by a distance, and the distances between adjacent electrodes 130 are not equal. In some embodiments, the distances between adjacent electrodes 130 are increasing or decreasing along the direction Y. In some embodiments, the distances between adjacent electrodes 130 are randomly arranged along the direction Y. In some embodiments, the distances between adjacent electrodes 130 are increased or decreased by degrees along the direction Y across the sensing area SA.

In some embodiments of the present disclosure, the electrode layer 13 covers between 2% to 50% of the bending area. In some embodiments, a ratio of the width D13 of the electrode 130 to a minimum bend radius of the flexible touch film is in a range to 1:2 and 1:15. In some embodiments, a ratio of the width D13 of the electrode 130 to a length L_{BA} of the bending area along the direction Y or a bending direction (the bending direction of a subject represents a direction of between two terminals of the subject bended toward each other, the bending direction is usually perpendicular to a bending axis of the subject, and the bending axis in the embodiments is along the direction X) is in a range of 1:20 and 1:6.

In some embodiments, the electrode layer 11 is transparent, flexible and conductive. Material of the electrode layer 11 can be transparent conducting oxide, polymer, composition, nanotube or combination thereof, such as indium tin oxide (ITO), lithium-fluorine-doped tin oxide (LFTO), silver nanowire, cadmium oxide (CdO), poly(3,4-ethylenedioxythiophene) (PEDOT), tin dioxide (SnO₂), indium zinc oxide (IZO), indium trioxide (In₂O₃), zinc oxide (ZnO), Poly(3,4-ethylenedioxythiophene) polystyrene sulfonate) (PEDOT-PSS), polyaniline (PANi), magnesium hydroxide material (e.g. Mg(OH)₂ C), carbon nanotube (CNT) and like materials.

In some embodiments, the electrode layer 13 is transparent, flexible and conductive. Material of the electrode layer 13 can be transparent conducting oxide, polymer, composition, nanotube, nanowire or combination thereof, such as indium tin oxide (ITO), lithium-fluorine-doped tin oxide (LFT0), silver nanowire, indium zinc oxide (IZO), cadmium oxide (CdO), poly(3,4-ethylenedioxythiophene) (PEDOT), tin dioxide (SnO₂), indium trioxide (In₂O₃), zinc oxide (ZnO), Poly(3,4-ethylenedioxythiophene) polystyrene sulfonate) (PEDOT-PSS), polyaniline (PANi), magnesium hydroxide material (e.g. Mg(OH)₂ C), carbon nanotube (CNT), silver nanowire, copper nanowire, aluminum nanowire and like materials.

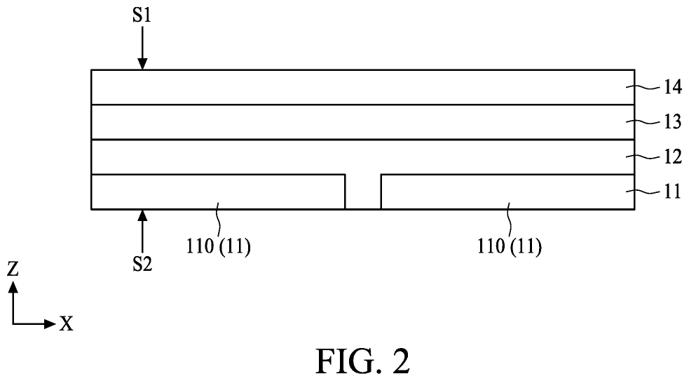

In the embodiment as shown in FIGS. 1-4, the electrode layer 13 is disposed on an outside curvature and the electrode layer 11 is disposed on an inside curvature when the flexible touch film TF1 is bent. Under the condition of the flexible touch film TF1 being bent, the electrode layer 11 has a bend radius smaller than that of the electrode layer 13. The flexible touch film TF1 can be applied to a flexible display device, and usually an interaction interface of the device is outward when the device is bent or folded. The flexible touch film TF1 may further include an insulator 14 proximal to an input surface S1 of the flexible touch film TF1 for protection. In the embodiment shown in FIGS. 1-4, the insulator 14 is proximal to the electrode layer 13 and distal to the electrode layer 11, the electrode layer 13 is proximal to the sensing surface S1 of the flexible touch film TF1 and distal to a display surface S2 of the flexible touch film TF2, and the electrode layer 11 is proximal to the display surface S2. and distal to the sensing surface Si, wherein the display surface S2 is opposite to the sensing surface S1 of the flexible touch film TH. The electrode layer 13 is between the insulator 14 and the insulator 12 along the direction Z. However, the insulator 14 is optional to be included if the flexible touch film TF1 is applied to a device with further encapsulate or package process. The input surface S1 is the surface of the flexible touch film TF1 receives signal to control the information system of the display device, and the display surface S2 is the surface proximal to the display device, e.g. an OLED display panel.

The flexible touch film TF1 further includes several contacts 131 in an area PA outside the sensing area SA. For example, a pair of the contacts 131 is at two opposite sides of the sensing area SA. The area PA can be, for example, in an interconnection region of a display panel (when the flexible touch film TF1 is applied to the panel), in a non-flexible area of the flexible touch film, adjacent to and around the sensing area SA, or peripheral to the sensing area SA inside the bending area BA, and it is not limited herein. As in some embodiments of at least a portion of the contact 131 being in the bending area BA, the sensing area is between two adjacent contacts 131 and covers at least a portion of one contact 131. In the embodiment shown in FIG. 1, the sensing area BA is between two adjacent contacts 131 and covers portions of the two adjacent contacts 131. The electrodes 130 can be in a configuration of several lines (or bars), and each line (i.e. the electrode 130) are, but not limited to, parallel to one another along the direction X across the sensing area SA of the flexible touch film TF1. A pair of contacts 131 is electrically connected with several electrodes 130 to form an electrode unit, and several electrode units are included in the flexible touch film TF1 In other words, one of the electrode units includes several electrode 130s (for example, at least 10 lines) and one corresponding pair of the contacts 131, and each one of the electrodes 130 is electrically connected with the corresponding contacts 131. In the embodiment shown in FIG. 1, the flexible touch film TF1 includes several electrodes 130, and an individual electrode 130 is connected with a pair of the contacts 131 at two opposite sides of the sensing area SA. In addition, the sensing area SA is, but not limited to, overlapping with two of the adjacent electrodes.

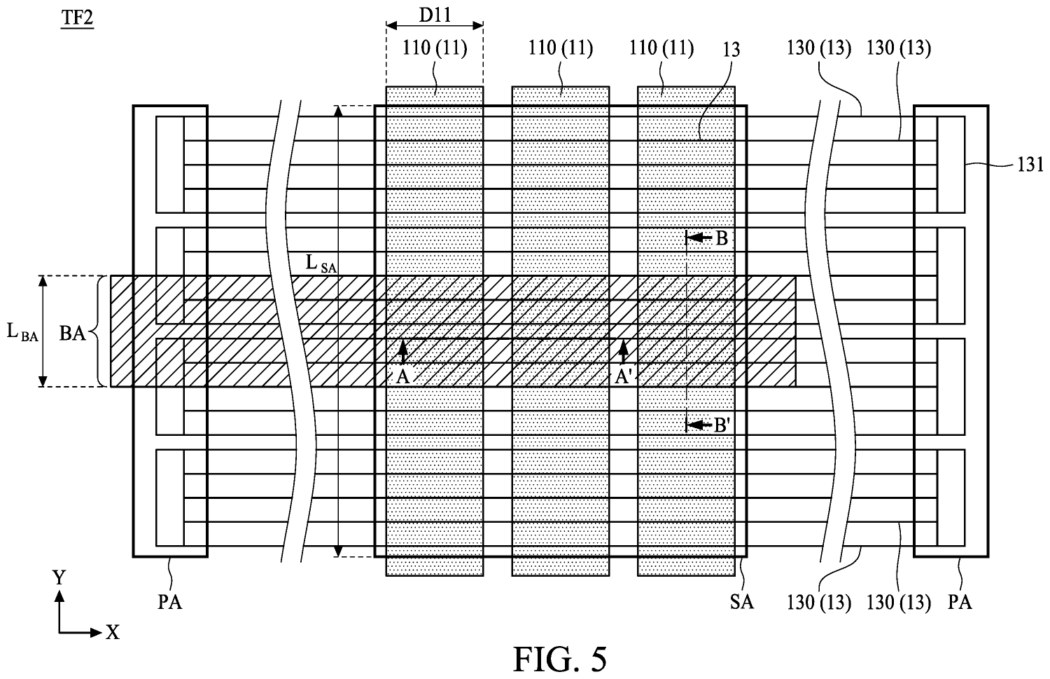

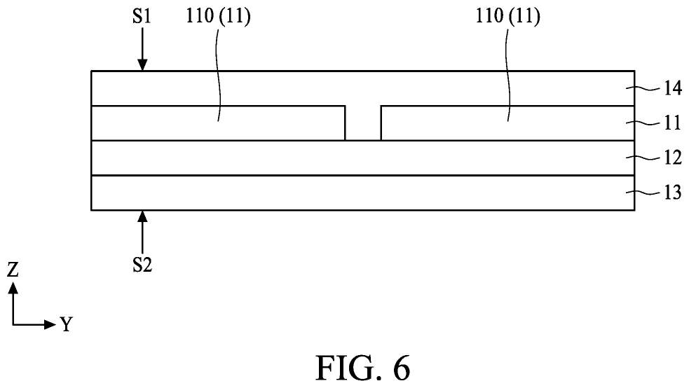

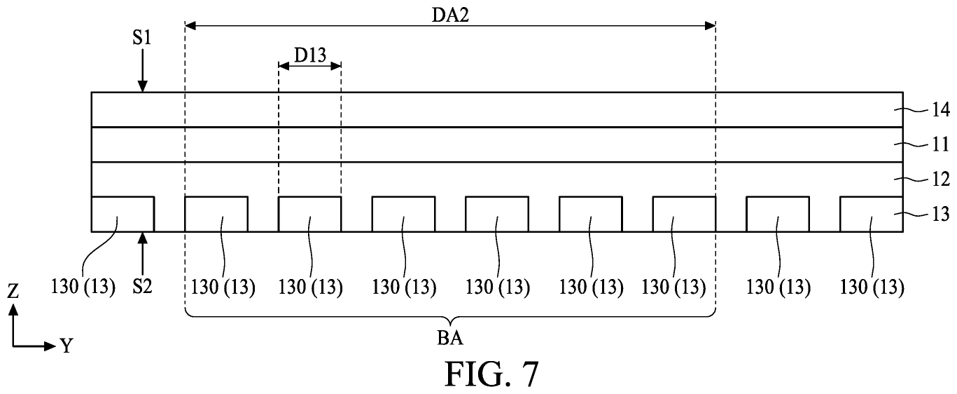

In some embodiments, the electrode layer 11 is proximal to the sensing surface S1 and distal to the display surface S2, and the electrode layer 13 is proximal to the display surface S2 and distal to the sensing surface S1. Referring to FIGS. 5-8, FIG. 5 shows a top view of a sensing area SA of a flexible touch film TF2 in accordance with an embodiment of the present disclosure, FIG. 6 and FIG. 7 are cross sections of the flexible touch film TF2 along a line A-A′ and a line B-B′ respectively in FIG. 5, and FIG. 8 is a cross section of the flexible touch film TF2 along the line B-B′ when the flexible touch film TF2 is bent to its minimum bend radius. Properties and arrangement of elements of the flexible touch film TF2 are similar to those of the flexible touch film TF1, and it is omitted in the following description of the flexible touch film TF2 for the purpose of brevity.

A difference between the flexible touch film TF2 and the flexible touch film TF1 is positions of the electrode layer 11 and the electrode layer 13. The electrode layer 13 in the embodiment is proximal to a display surface S2 of the flexible touch film TF2 and distal to a sensing surface S1 of the flexible touch film TF2. The electrode layer 11 is proximal to the display surface S2 and distal to the sensing surface Sl. The sensing surface S1 is opposite to the display surface S2 of the flexible touch film TF2. The flexible touch film TF2 can be applied to a display surface on the surface S2. The input surface S1 being the surface of the flexible touch film TF2 receives input signal to control the information system of the display, and the display surface S2 is the surface proximal to (or attached to) the display device, e.g. an OLED display panel. The flexible touch film TF2 optionally includes an insulator 14 proximal to the sensing surface S1 and the electrode layer 11 and distal to the display surface S2. The electrode layer 11 is between the insulator 14 and the insulator 12 along the direction Z. In the embodiment as shown in FIGS. 5-8, the electrode layer 11 is disposed on an outside curvature and the electrode layer 13 is disposed on an inside curvature when the flexible touch film TF2 is bent. Under the condition of the flexible touch film TF2 being bent, the electrode layer 11 has a bend radius smaller than that of the electrode layer 13.

As shown in FIG. 8, the flexible touch film TF2 has a minimum bend radius R2. Even a minimum bend radius of the electrode layer 11 is greater than that of the electrode layer 13, the discontinuous extension of the electrode layer 13 on the direction Y provides a good flexibility to the flexible touch film TF2 when the flexible touch film TF2 is bent along the direction X. In other words, when the flexible touch film TF2 is bent along the direction X, the discontinuous extension of the electrode layer 13 along an direction perpendicular to the direction X (i.e. the direction Y in the embodiment) can provide good flexibility to the flexible touch film TF2 even the electrode layer 13 is disposed on an inside curvature and the electrode layer 11 is disposed on an outside curvature. The minimum bend radius R2 may be smaller than or equal to the minimum bend radius R1 attributed to the discontinuous arrangement of the electrode layer 13, but relationship of the minimum bend radius R2 and the minimum bend radius R1 is not limited herein.

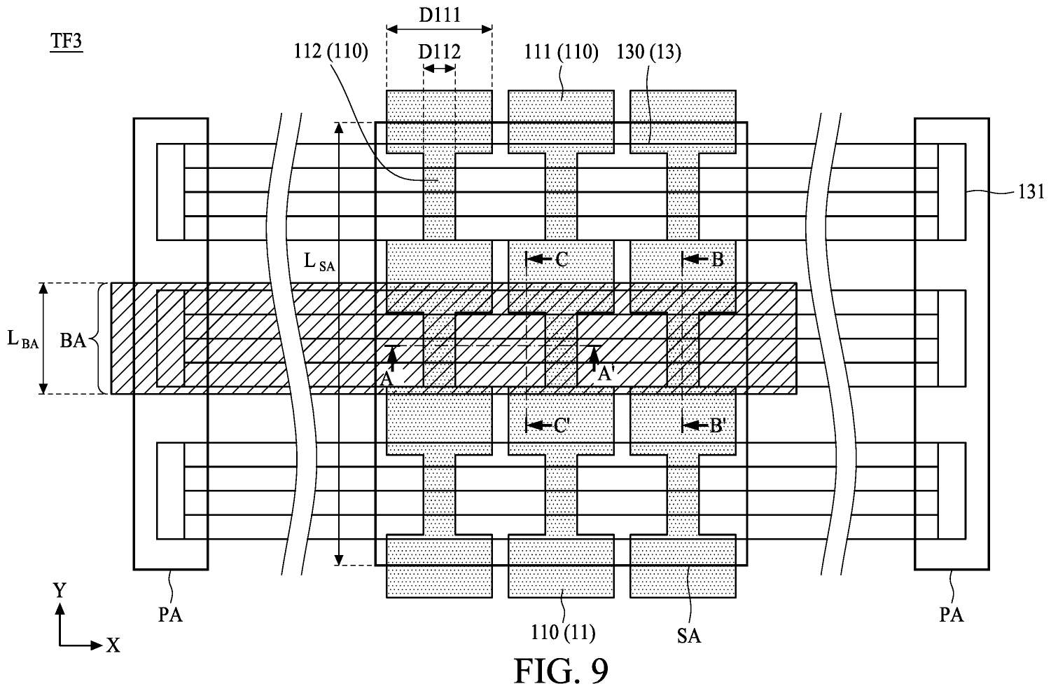

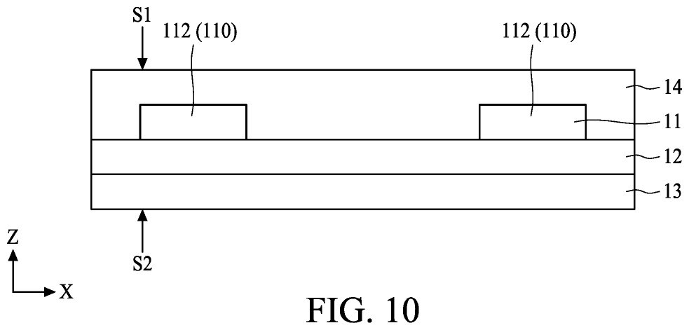

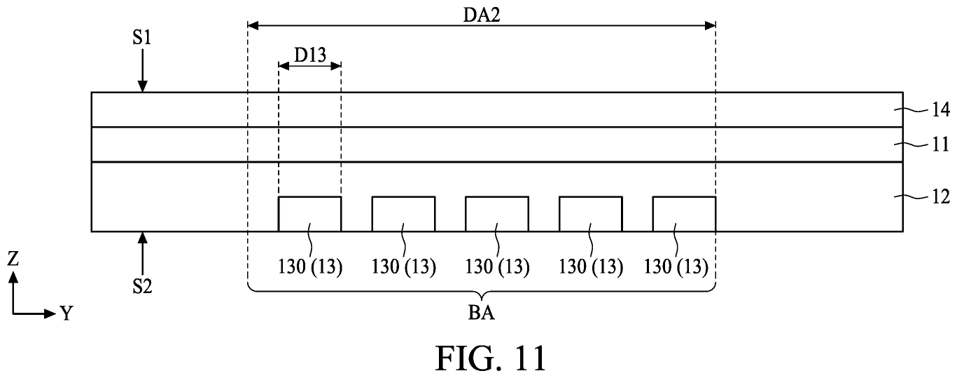

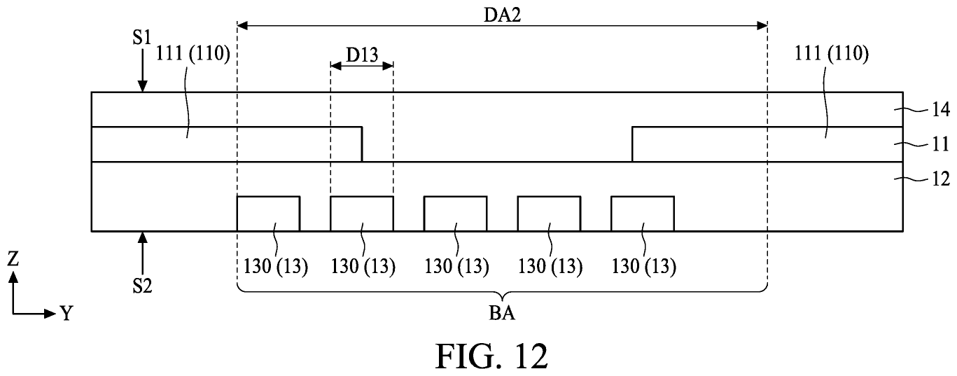

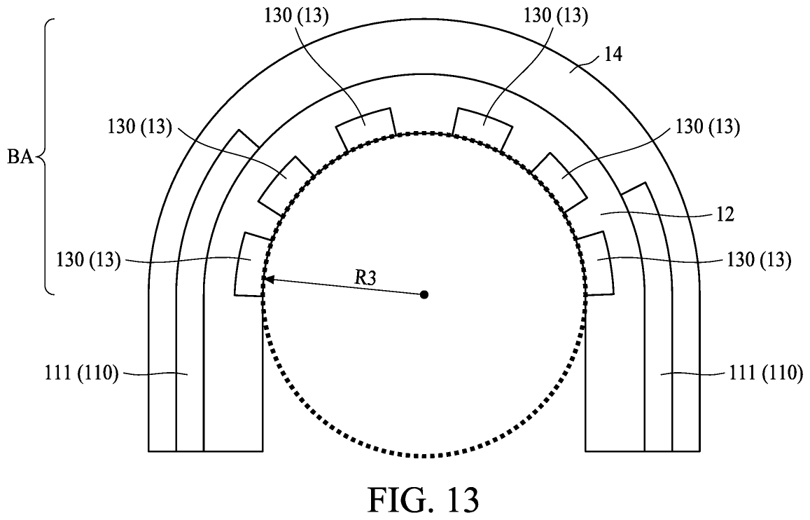

In some embodiments to disperse possible tensile pressure on the outer electrode layer 13 of the flexible touch film TF2 as illustrated in FIGS. 5-8, a shape of the electrode layer 13 can be modified. Referring to FIGS. 9-13, FIG. 9 shows a top view of a sensing area SA of a flexible touch film TF3 in accordance with an embodiment of the present disclosure, FIGS. 10-12 are cross sections of the flexible touch film TF3 along a line A-A′, a line B-B′ and a line C-C′ respectively in FIG. 9, and FIG. 13 is a cross section of the flexible touch film TF3 along the line C-C′ when the flexible touch film TF3 is bent to its minimum bend radius R3.

In the embodiment, the electrode layer 13 is proximal to a display surface S2 of the flexible touch film TF3 and distal to a sensing surface S1 of the flexible touch film TF3. The electrode layer 11 is proximal to the display surface S2 and distal to the sensing surface S1, wherein the sensing surface Si is opposite to the display surface S2 of the flexible touch film TF3. The input surface S1 is the surface of the flexible touch film TF3 receives input signal to control the information system of a display device when the flexible touch film TF3 is applied to the display device, and the display surface S2 is the surface proximal to the display device, e.g. an OLED display panel. In the embodiment, the electrode layer 11 is disposed on an outside curvature and the electrode layer 13 is disposed on an inside curvature when the flexible touch film TF3 is bent. Under the condition of the flexible touch film TF3 being bent, the electrode layer 13 has a bend radius smaller than that of the electrode layer 11. The flexible touch film TF3 optionally includes an insulator 14 proximal to the sensing surface S1 and the electrode layer 11 and distal to the display surface S2. The electrode layer 11 is between the insulator 14 and the insulator 12 along a direction Z.

Moreover, the electrode 110 of the electrode layer 11 includes several parts 111 and several parts 112. The part 111 has a width D111 on a direction X, and the part 112 has a width D112 on the direction X. The width D111 is greater than the width D112. The parts 111 and the parts 112 of one electrode 110 are intervally arranged and connected to each other along a direction Y. The direction X is substantially perpendicular to the direction Y, and the direction Z is substantially perpendicular to the direction X and the direction Y. In some embodiments of the flexible touch film TF3 as shown in FIG. 9, FIG. 10 and FIG, 12, a bending area BA covers at least a portion of one part 112 and optionally at least a portion of one part 111. In such embodiments, the bending area BA covers a part 112 and portions of two adjacent parts 111 on the Y direction; and in other embodiments, the part 112 traverses substantially the entire bending area on the direction Y. The flexible touch film TF3 includes several electrodes 110, each of the electrodes 110 extends along the direction Y and traverses the sensing area SA of the flexible touch film TF3 on the direction Y, and the electrodes 110 are arranged along the direction X side by side.

In the embodiment of the flexible touch film TF 3, it shows an example of a different discontinuous arrangement of the electrode layer 13 from that of the flexible touch films TF1 and TF2. The electrodes 130 are in a configuration of several lines (or bars), and each line (i.e. the electrode 130) are parallel to one another along the direction X across the sensing area SA of the flexible touch film TF3. The flexible touch film TF3 includes several electrodes 130 and several contacts 131 in an area PA outside the sensing area SA, and a pair of the contacts 131 is electrically connected with several electrodes 130 to form an electrode unit. The contacts 131 can be inside or outside the bending area BA, and in the embodiment of the flexible touch film TF3, the bending area BA covers at least a contact 131. In the embodiment, the electrode layer 13 traverses substantially an entire contact 131 on the direction Y. Opposite ends of the electrodes 130 are respectively connected to the other contact 131 of the pair of the contacts 131 at two opposite sides of the sensing area SA. One of the electrode unit traverses the several parts 112 of the several electrodes 110 along the direction X, and optionally portions of the parts 111 of the several electrodes 110 on the direction X. A distance between two adjacent electrode units is greater than a distance between two adjacent lines the electrode 130).

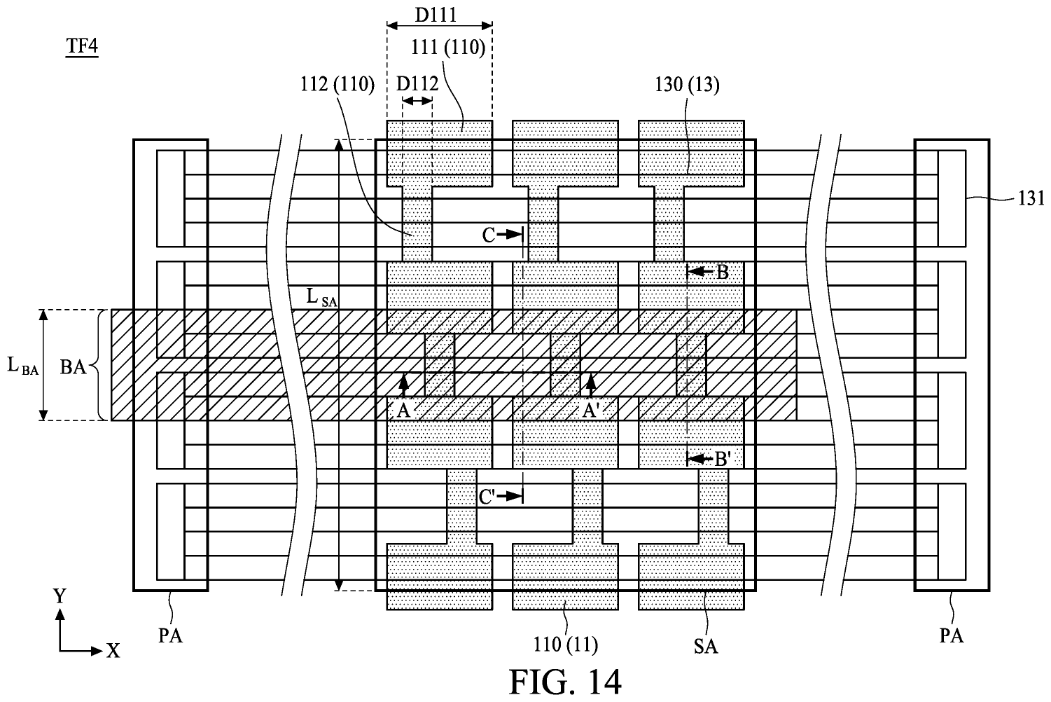

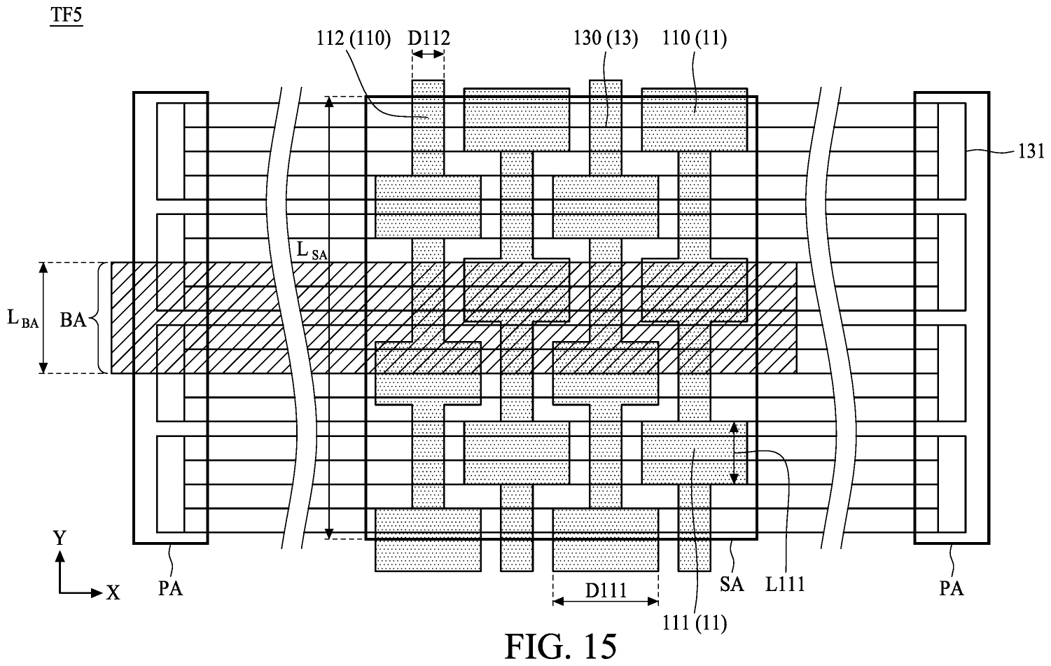

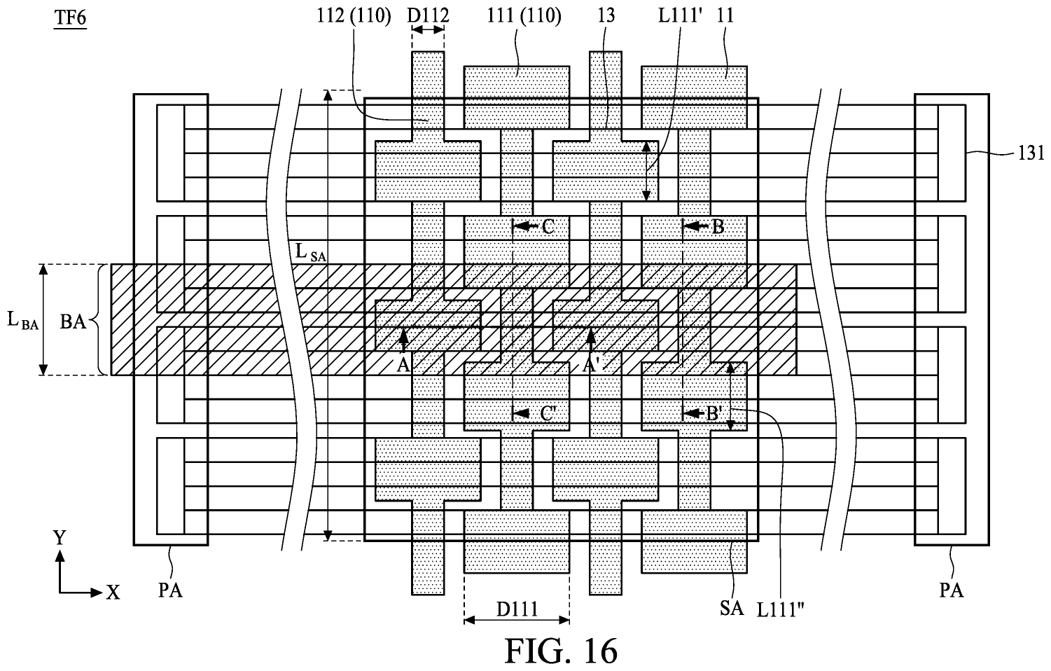

A position of the part 112 relative to a position of the part 111 of the electrode 110 is not limited herein, and an implementation of the electrodes 130 in an embodiment can be combined with an implementation of the electrodes 110 in another embodiment. For example as shown in FIG. 9, a central line of a part 112 of the flexible touch film TF3 is substantially aligned to a central line of a parts 111 on the direction Y, and the electrode units of the flexible touch film TF3 is arranged in less density in the sensing area SA than that of the electrode units of the flexible touch film TF1. For another example as shown in FIG. 14 in accordance with a flexible touch film TF4 of an embodiment of the present disclosure, a part 112 of an electrode HO is connected to a right hand side of a part 111 of the electrode 110 on the direction Y, or a left hand side of a part 111 of the electrode 110 on the direction Y, or a central of a part 111 of the electrode 110 on the direction Y. The electrode unit of the flexible touch film TF4 is similar to that of the flexible touch film TF1.

In an embodiment as shown in FIG. 15 in accordance with a flexible touch film TF5 of the present disclosure, the flexible touch film TF5 is similar to the flexible touch film TF4, and a difference between the flexible touch film TF5 and the touch film TF4 is that the flexible touch film TF5 has a part 111 of an electrode 110 between two parts 112 of two adjacent electrodes 110 on a direction X. Several parts 111 are arranged intervally between several parts 112 along a direction Y and the direction X, wherein the direction X is substantially perpendicular to the direction Y. In addition, the parts 111 of one electrode 110 overlaps with the parts 111 of an adjacent electrode 110 along the direction Y form a top view perspective. One part 111 has a length L111 along the direction Y and a width D111 along the direction X. The length L111 and the width D111 are constant among the parts 111 of the several electrodes 110. A width along the direction X and a length along the direction Y of a part 112 of an electrode 110 are constant among the several electrodes 110.

In an embodiments as shown in FIG. 16 in accordance with a flexible touch film TF6 of the present disclosure, the flexible touch film TF6 is similar to the flexible touch film TF4, and a difference between the flexible touch film TF6 and the touch film TF5 is that the flexible touch film TF6 has various lengths L111 of parts 111 of two adjacent electrodes 11 along a direction Y. As shown in FIG. 16, a part 111 of an electrode 110 has a length L111′ along the direction Y, and a part of an adjacent electrode 110 has a length L111″, wherein the length L111″ is greater than the length L111′. One part 111 has a width D111 along a direction X, and the width D111 is constant among the parts 111 of the several electrodes 110. A width along the direction X and a length along the direction Y of a part 112 are constant among the several electrodes 110. In addition, the parts 111 of one electrode 110 overlaps with the parts 111 of an adjacent electrode 110 along the direction Y form a top view perspective. Top views of different flexible touch films of the present disclosure can be various depending on sensitivity required.

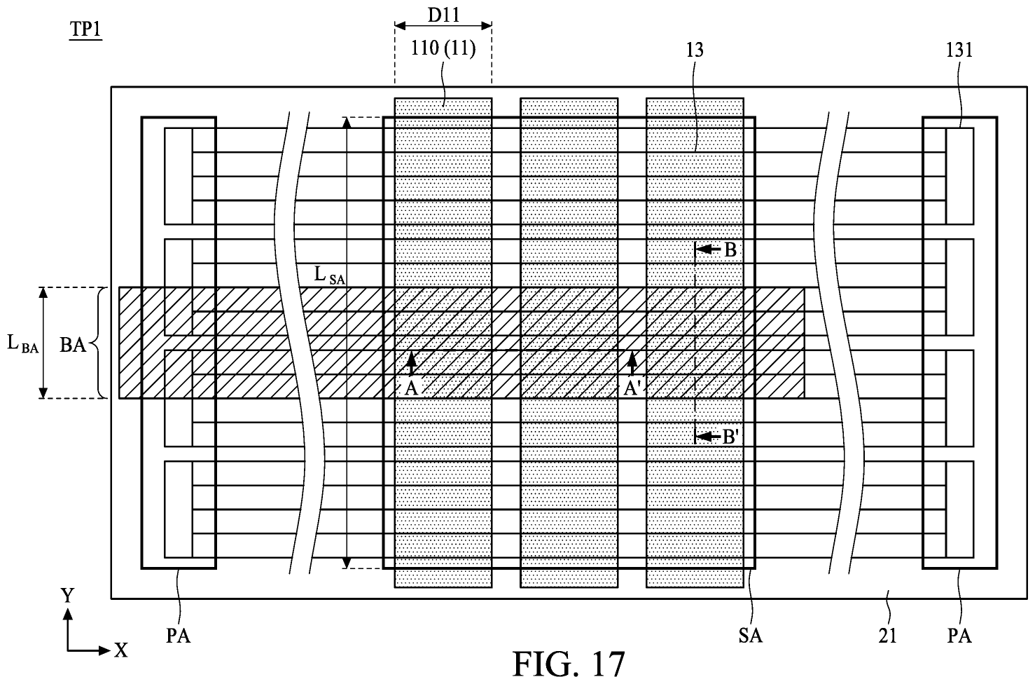

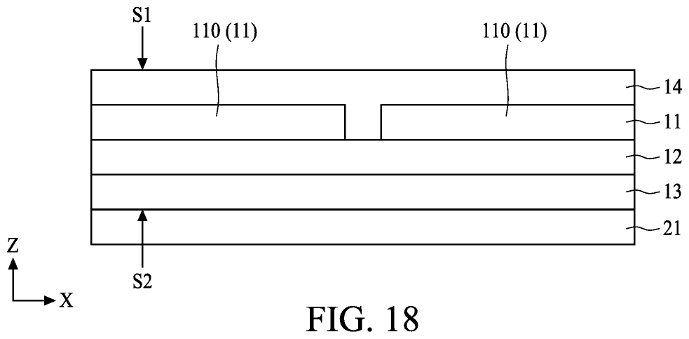

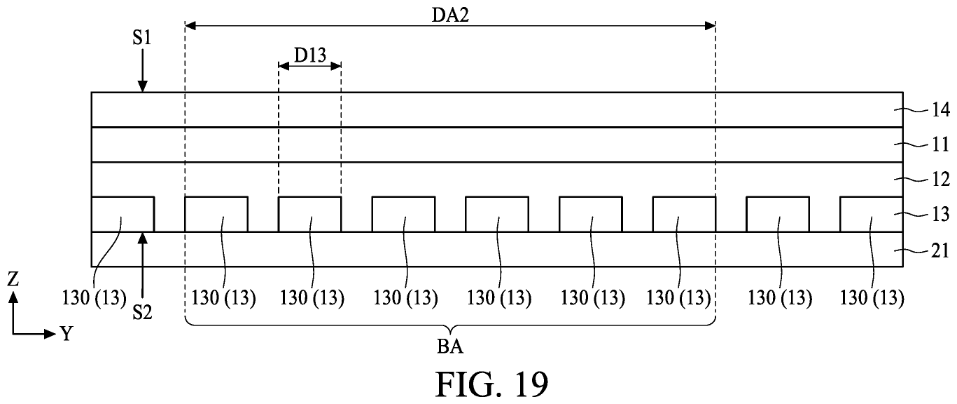

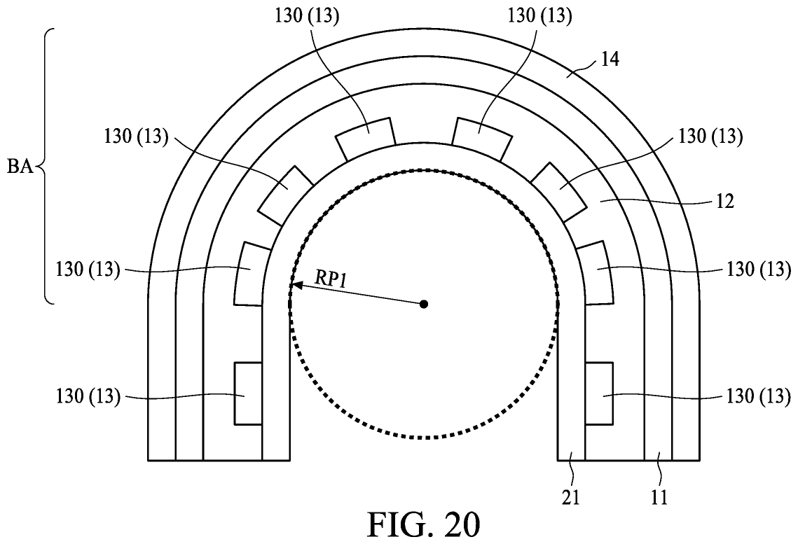

A flexible touch film can be applied to a flexible display device or a flexible display panel, e.g. an OLED display substrate, an AMOLED display substrate, and a. digital paper. As shown in FIGS. 17-20, FIG. 17 shows a top view of a sensing area SA of a flexible touch device TP1 in accordance with an embodiment of the present disclosure, FIG. 18 and FIG. 19 are cross sections of the flexible touch device TP1 along a line A-A′ and a line B-B′ respectively in FIG. 17, and FIG. 20 is a cross section of the flexible touch device TP1 along the line B-B′ when the flexible touch device TP1 is bent to its minimum bend radius RP1. The flexible touch device TP1 includes the flexible touch film TF1 as shown in FIGS. 1-4 and a substrate 21 disposed on a display surface S2 of the touch film TF1. An electrode layer 11 is between the substrate 21 and an insulator 12. The substrate 21 in the embodiment is an OLED display panel. The flexible touch device TP1 shows an application of a flexible touch film of the present disclosure.

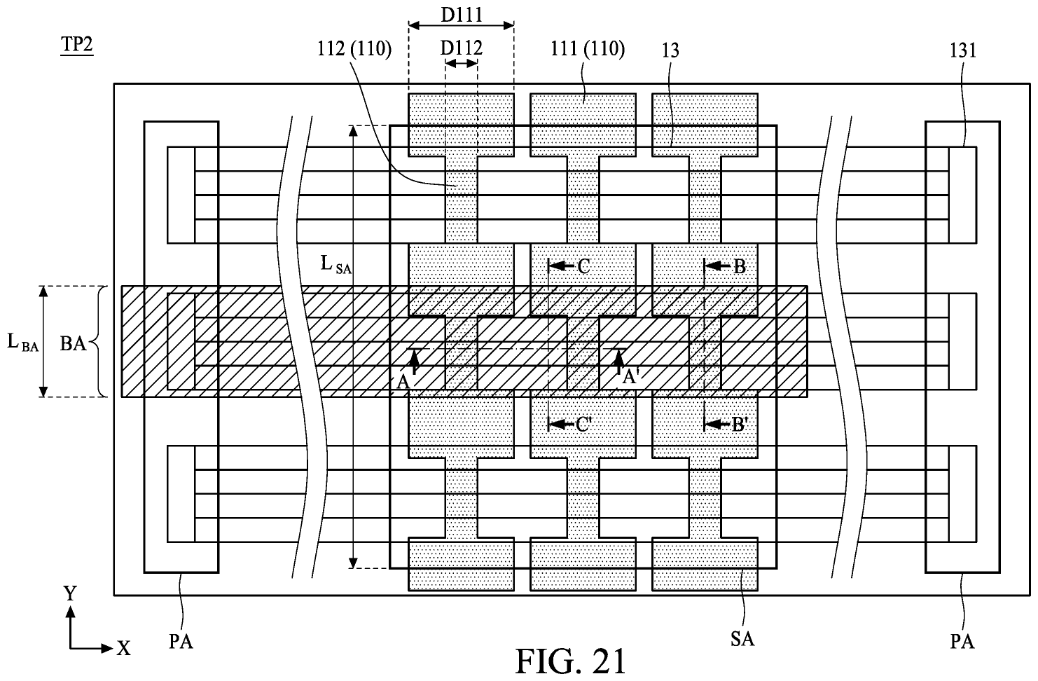

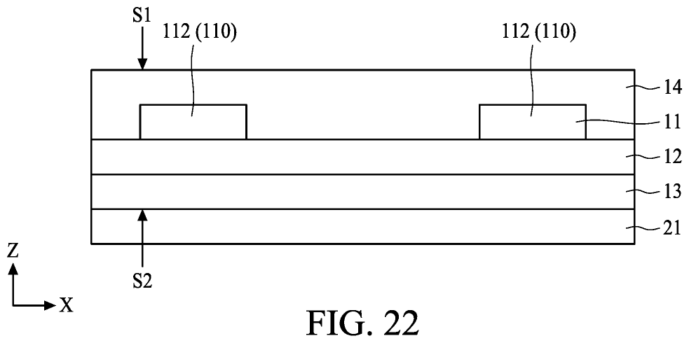

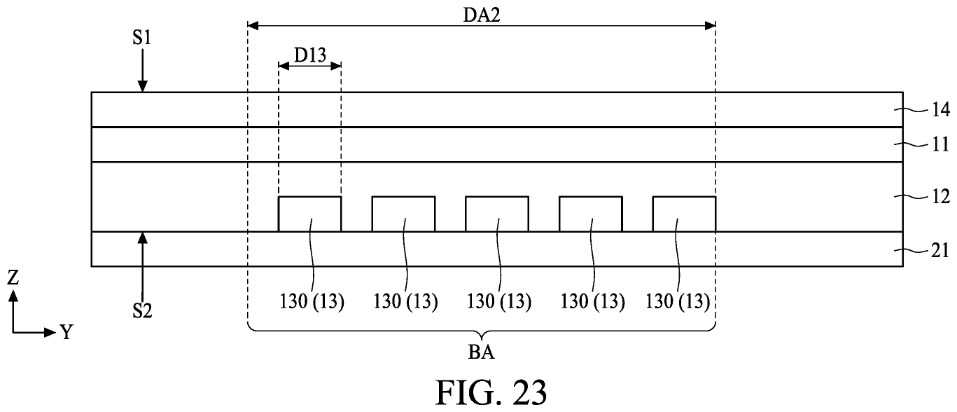

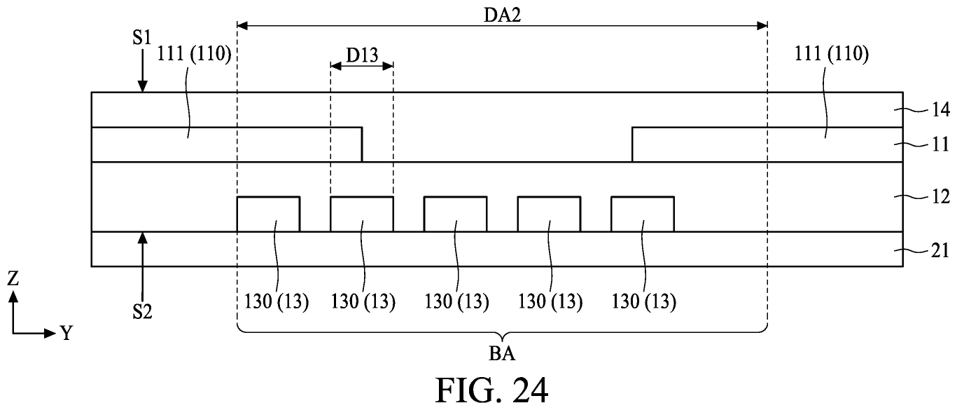

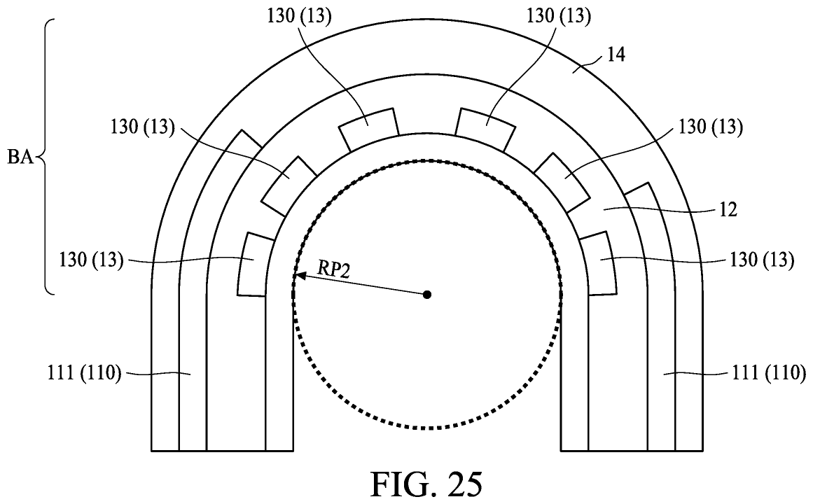

FIGS. 21-25 show a flexible touch device TP3 in accordance with an embodiment of the present disclosure, as another example of a flexible touch film as illustrated above being applied to a flexible device. FIG. 21 shows a top view of a sensing area SA of the flexible touch device TP3, FIGS. 22-24 are cross sections of the flexible touch device TP3 along a line A-A′, a line B-B′ and a line C-C′ respectively in FIG. 21, and FIG. 25 is a cross section of the flexible touch device TP3 along the line C-C′ when the flexible touch device TP3 is bent to its minimum bend radius RP2. The flexible touch device TP2 includes the flexible touch film TF3 as shown in FIGS. 9-13 and a substrate 21 disposed on a display surface S2 of the touch film TF3. An electrode layer 13 is between the substrate 21 and an insulator 12. The substrate 21 in the embodiment is an AMOLED display panel. The flexible touch device T21 shows an application of a flexible touch film of the present disclosure. The flexible touch films as illustrate above and those not illustrated but within the scope of the present disclosure can be applied to a flexible display device. It is not limited herein.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A flexible touch film, comprising:
a first electrode layer extending continuously along a first direction;
a second electrode layer extending continuously along a second direction and discontinuously along the first direction, the first direction being substantially perpendicular to the second direction, wherein the second electrode layer includes a plurality of electrodes;
an insulator disposed between the first electrode layer and the second electrode layer; and
a pair of contacts, disposed on two opposite sides of the electrode along the second direction, wherein the pair of contacts electrically connects to a same electrode of the plurality of electrodes.

2. The film of claim 1, wherein a material of the first electrode layer is different from that of the second electrode layer.

3. The film of claim 1, wherein a minimum bend radius of the first electrode layer is smaller than a minimum bend radius of the second electrode layer.

4. The film of claim 1, further comprising a bending area across a sensing area of the flexible touch film along the second direction, wherein a percentage of an area coverage of the second electrode layer distributed in the bending area is (a bend radius of the film/a length of the sensing area along the second direction in a bending status)*100% when the film is bent.

5. The film of claim 1, wherein the second electrode layer is discontinuously and evenly distributed in the bending area along the first direction.

6. The film of claim 1, wherein the plurality of electrodes extends along the second direction and is disposed in parallel along the first direction, and distances between adjacent electrodes are different along the first direction.

7. The film of claim 6, the distances between adjacent electrodes are ascending along the first direction.

8. The film of claim 1, wherein the first electrode layer, the insulator and the second electrode layer are stacked in sequence, and the first electrode layer has a bend radius smaller than that of the second electrode layer when the film is bent.

9. The film of claim 1, wherein the second electrode layer, the insulator and the first electrode layer are stacked in sequence, and the second electrode layer has a bend radius smaller than that of the first electrode when the film is bent.

10. The film of claim 9, wherein the first electrode layer comprises:
a first part having a first width on the second direction; and
a second part having a second width on the second direction, the second width being smaller than the first width.

11. The film of claim 9, wherein the second part traverses the bending area on the first direction.

12. A flexible touch device, comprising:
a substrate;
a first electrode layer extending continuously along a first direction over the substrate;
a second electrode layer extending continuously along a second direction and discontinuously along the first direction over the substrate, the first direction being perpendicular to the second direction, wherein the second electrode layer includes a plurality of electrodes;
an insulator disposed between the first electrode layer and the second electrode layer; and
a pair of contacts, disposed on two opposite sides of the electrode along the second direction, wherein the pair of contacts electrically connects to a same electrode of the plurality of electrodes.

13. The device of claim 12, wherein the substrate is a flexible display panel.

14. The device of claim 12, wherein a material of the first electrode layer is different from that of the second electrode layer.

15. The device of claim 12, wherein a minimum bend radius of the first electrode layer is smaller than a minimum bend radius of the second electrode layer.

16. The device of claim 12, wherein the first electrode layer is between the substrate and the insulator.

17. The device of claim 12, wherein the plurality of electrodes is electrically connected with a plurality of pairs of contacts, and a bending area of the device is between two adjacent pairs of contacts.

18. The device of claim 12, wherein the second electrode layer is between the substrate and the insulator.

19. The device of claim 12, wherein each of the pair of contacts traverses a bending area of the device.

20. The device of claim 12, wherein the first electrode layer comprises:
a first part having a first width on the second direction; and
a second part having a second width on the second direction, the second width being smaller than the first width.
